(19) United States
(12) Patent Application Publication
(10) Pub. No.: US 2026/0063718 A1
(43) Pub. Date: Mar. 5, 2026

(54) DETECTION OF RELAY CONTACTOR MOVEMENT

(71) Applicant: Allegro MicroSystems, LLC, Manchester, NH (US)

(72) Inventors: Kavul Tshiloz, Edinburgh (GB); Narasimhan Trichy, Plano, TX (US); Andrea Foletto, Andorno Micca (IT)

(73) Assignee: Allegro MicroSystems, LLC, Manchester, NH (US)

(21) Appl. No.: 18/948,920

(22) Filed: Nov. 15, 2024

Related U.S. Application Data
(63) Continuation-in-part of application No. 18/818,751, filed on Aug. 29, 2024.

(51) Int. Cl. G01R 31/327

(52) U.S. Cl. CPC G01R 31/3278

(57) ABSTRACT

A method, comprising: generating a comparison signal S_{P} having a first value when a voltage that is applied at one end of a contactor coil of a relay is above a threshold V_{P} and a second value when the voltage is below the threshold V_{P}; generating a comparison signal S_{D} having the first value when the voltage is above a threshold V_{D} and the second value when the voltage is below the threshold V_{D}; detecting whether the relay is in a faulty state based on the comparison signals S_{P} and S_{D}; and generating an indication of a fault when the relay is detected to be in a faulty state.

### CLAIM OF PRIORITY

The present application is filed as a Continuation-in-Part application of U.S. application Ser. No. 18/818,751 (Atty. Docket No. ALLEG-A376PUS), filed on Aug. 29, 2024, and entitled: Detection of Relay Contactor Movement, which is herein incorporated by reference in its entirety.

### BACKGROUND

Relays are electro-mechanical devices that play a crucial role in controlling electrical circuits. They act as switches that can open or close an electrical connection when an external signal is applied. Essentially, relays serve as intermediaries between low-voltage control systems and high-voltage power circuits, ensuring the safety and efficiency of electrical operations. They are used in a wide range of applications, from industrial automation and manufacturing to telecommunications and automotive systems. Relays are especially valuable when there is a need to isolate low-voltage control circuits from high-voltage or high-current circuits to prevent damage to sensitive components or to control complex sequences of operations.

### SUMMARY

According to aspects of the disclosure, a method is provided, comprising: generating a comparison signal S_{P} having a first value when a voltage that is applied at one end of a contactor coil of a relay is above a threshold V_{P} and a second value when the voltage is below the threshold V_{P}; generating a comparison signal S_{P} having the first value when the voltage is above a threshold V_{D} and the second value when the voltage is below the threshold V_{D}; detecting whether the relay is in a faulty state based on the comparison signals S_{P} and S_{D}; and generating an indication of a fault when the relay is detected to be in a faulty state.

According to aspects of the disclosure, a system is provided, comprising: a first comparator that is configured to generate a comparison signal S_{P}, the comparison signal S_{P} having a first value when a voltage that is applied at one end of a contact coil of a relay is above a threshold V_{P} and a second value when the voltage is below the threshold V_{P}; a second comparator that is configured to generate a comparison signal S_{D}, the comparison signal S_{D} having the first value when the voltage is above a threshold V_{D} and the second value when the voltage is below the threshold V_{D}; and a processing circuitry that is configured to detect whether the relay is in a faulty state based on the comparison signals S_{P} and S_{D}, and generate an indication of a fault when the relay is detected to be in a faulty state.

According to aspects of the disclosure, a method is provided, comprising: detecting a metric of a relay; detecting whether the metric has crossed a threshold; when the metric has crossed the threshold, detecting a duration for which the metric remains past the threshold; and generating an unintended movement error when the metric remains past the threshold for less than a lower bound duration.

According to aspects of the disclosure, a system is provided, comprising: a processing circuitry configured to: detect a metric of a relay; detect whether the metric has crossed a threshold; when the metric has crossed the threshold, detect a duration for which the metric remains past the threshold; and generate an unintended movement error when the metric remains past the threshold for less than a lower bound duration.

### BRIEF DESCRIPTION OF THE DRAWINGS

The foregoing features may be more fully understood from the following description of the drawings in which:

FIG. 1 is a diagram of an example of an electromagnetic relay, according to aspects of the disclosure;

FIG. 2 is a diagram of an example of a driving circuitry of the electromagnetic relay of FIG. 1, according to aspects of the disclosure;

FIG. 3 is a diagram of an example of a fault detector, according to aspects of the disclosure;

FIG. 4 is a graph illustrating aspects of the operation of the fault detector of FIG. 3, according to aspects of the disclosure;

FIG. 5 is a flowchart of an example of a process, according to aspects of the disclosure;

FIG. 6A is a graph illustrating aspects of the operation of the fault detector of FIG. 3, according to aspects of the disclosure;

FIG. 6B is a graph illustrating aspects of the operation of the fault detector of FIG. 3, according to aspects of the disclosure;

FIG. 7A is a graph illustrating aspects of the operation of the fault detector of FIG. 3, according to aspects of the disclosure;

FIG. 7B is a graph illustrating aspects of the operation of the fault detector of FIG. 3, according to aspects of the disclosure;

FIG. 8A is a diagram of an example of a fault detector, according to aspects of the disclosure;

FIG. 8B is a graph illustrating aspects of the operation of the fault detector of FIG. 8A; according to aspects of the disclosure;

FIG. 8C is a flowchart of an example of a process that is performed by the fault detector of FIG. 8B;

FIG. 9A is a diagram of an example of a fault detector, according to aspects of the disclosure;

FIG. 9B is a graph illustrating aspects of the operation of the fault detector of FIG. 9B; according to aspects of the disclosure; and

FIG. 9C is a flowchart of an example of a process that is performed by the fault detector of FIG. 9B.

### DETAILED DESCRIPTION

The present disclosure provides various techniques for detecting malfunctions in a relay. The relay may be part of the battery disconnect unit (BDU) of an electric vehicle. In an electric vehicle, the BDU is a critical component that is arranged to disconnect the battery in case of failure that can lead to fire or explosion in the electric vehicle. In this regard, the techniques disclosed herein can be used to increase the fault tolerance of relays that are used in the BDUs of electric vehicles or any other safety-critical application. It will be understood that the present disclosure is not limited to any specific application of the techniques disclosed herein.

In electric vehicle applications, a relay may be provided with high-voltage (HV) contactors that offer a low-voltage control for engaging and disengaging a metal plate to connect or disconnect the studs of a high-voltage current path. As safety is paramount in the design of electric vehicles, the HV contactors play a critical role in ensuring it. In emergency situations, such as collision or fault detection, HV contactors can rapidly disconnect the vehicle's battery system from the rest of the vehicle, reducing the risk of electric shock and fire hazards. Thus, suitable diagnostics on the state of HV contactor are required which provide information when the relay has been subjected to a mechanical shock, such as the shock that would be experienced when the electric vehicle is involved in a collision.

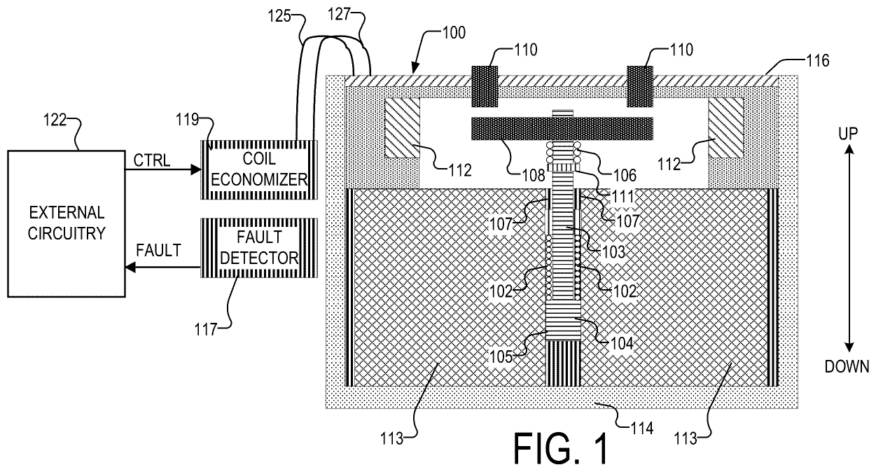

FIG. 1 is a schematic diagram of an example of an electromagnetic relay 100, according to aspects of the disclosure. As illustrated, the relay 100 may include a housing enclosure 114 arranged to contain a return spring 102 and a moving plunger 104. The moving plunger 104 may include a portion 103 and a portion 105. Portion 105 may be arranged to engage a return spring 102 that is disposed between portion 105 and a stop 107. A contactor 108 may be coupled to portion 103 of the plunger 104, as shown. The moving contact may be loosely coupled to portion 103 so that it can move up and down relative to portion 103. An overtravel spring 106 may be disposed between the contactor 108 and a collar 111. Permanent magnets 112 may be disposed adjacent to the contactor 108 and fixed contacts 110 may be disposed above the contactor 108. An epoxy hermetic seal 116 may be arranged to partially encapsulate the fixed contact 110 to prevent moisture from entering the housing enclosure 114.

According to the present example, relay 100 is provided with a coil economizer 119 and a fault detector 117. The coil economizer 119 may include a circuit that is used to reduce the power consumption of coil 113 and improve the efficiency and longevity of the relay 100. The fault detector 117 may include circuitry configured to detect faults in the relay 100. The fault detector may be configured to generate a fault signal FAULT. The signal FAULT may be provided to external circuitry 122 which is configured to operate the relay 100.

External circuitry 122 may include a microcontroller and/or any other suitable type of circuitry. External circuitry 122 may be configured to provide coil economizer 119 with a control signal CTRL. When signal CTRL is set to a first value (e.g., ‘1’), coil economizer 119 may toggle the relay 100 between the active and inactive states. When relay 100 is in the active state, the coil 113 is energized, which causes the plunger 104 to move up and bring contactor 108 into electrical contact with fixed contacts 110, thus allowing electrical current to flow from one of the contacts 110 to the other. Under the nomenclature of the present disclosure, the terms “active state” and “hold phase” are used interchangeably. When relay 100 is in the inactive state, coil 113 may be de-energized and the return spring 102 may cause the plunger 104 to be separated from the fixed contacts 110, thus interrupting the electrical connection between fixed contacts 110.

In the example of FIG. 1, relay 100 is provided with coil economizer 119, which is electrically coupled to coil 113 via lines 125 and 127. Each of lines 125 and 127 may include a wire, a conductive trace, and/or any other suitable type of conductive member. Lines 125 and 127 may be used to energize the coil 113 and close relay 100. Although, in the present example, relay 100 is provided with a coil economizer 119, in some implementations the coil economizer 119 may be omitted. In such implementations, lines 125 and 127 may be connected directly to the external circuitry 122. FIG. 1 is provided as an example only to illustrate one of many possible architectures that can be used to implement relay 100. In this regard, it will be understood that the relay 100 is not limited to having any specific configuration. Although, in the example of FIG. 1, coil economizer 119 and fault detector 117 are depicted as separate blocks, in some implementations, at least one of the fault detector 117 and/or coil economizer 119 may be integrated into the relay 100.

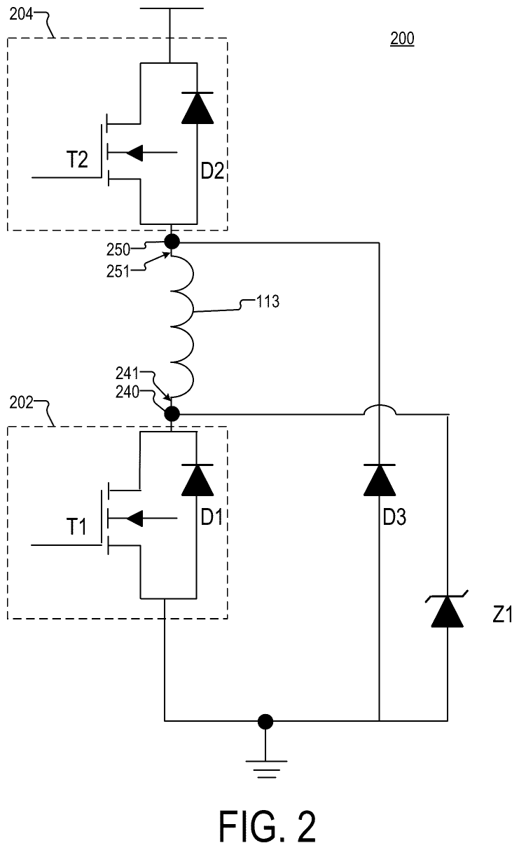

FIG. 2 is a diagram of an example of one possible implementation of a coil driver 200, according to aspects of the disclosure. The coil driver 200 may be part of the coil economizer 119 and/or any other suitable circuitry that is used to drive the relay 100. In some implementations, the coil driver 200 may be integrated into the relay 100. As illustrated, coil driver 200 includes circuitry 202 that is coupled to a first end 241 of coil 113 at a node 240, and a circuitry 204 that is coupled to a second end 251 of coil 113 at a node 250. The coil driver 200 also may include a Zener diode Z2 and a diode D3, as shown. Diode D3 may be coupled in parallel with circuitry 202 and the coil 113 between node 250 and a ground source. Circuitry 202 may include a transistor T1 and a diode D1. The transistor T1 and the diode D1 may be coupled in parallel between node 240 and the ground source. Specifically, node 240 may be coupled to the drain of transistor T1, the cathode of diode D1, and the end 241 of coil 113. The source of transistor T1 and the anode of diode D1 may be coupled to the ground source. Zener diode Z1 may be coupled in parallel with circuitry 202 between the node 240 and the ground source, such that the cathode of the Zener diode Z1 is coupled to end 241 of coil 113 and the anode of the Zener diode Z1 is coupled to the ground source. Circuitry 204 may include a transistor T2 and a diode D2 that are coupled in parallel between a voltage source and a node 250. Specifically, the drain of transistor T2, the anode of diode D2, and the end 251 of coil 113 may be coupled to node 250. In the present example, transistors T1 and T2 are metal-oxide-semiconductor field-effect transistors (MOSFETs). However, the present disclosure is not limited to any specific type of transistor being used.

FIG. 2 is provided as an example only. Although, in the example of FIG. 2, a Zener diode is used as a voltage clamp, it will be understood that alternative implementations of coil driver 200 are possible in which the Zener diode is replaced with another type of voltage clamp. Furthermore, the present disclosure is not limited to using any specific circuitry for driving the coil 113 of relay 100. In this regard, it will be understood that circuitry 202 and 204 can be replaced with any suitable type of driving circuitry.

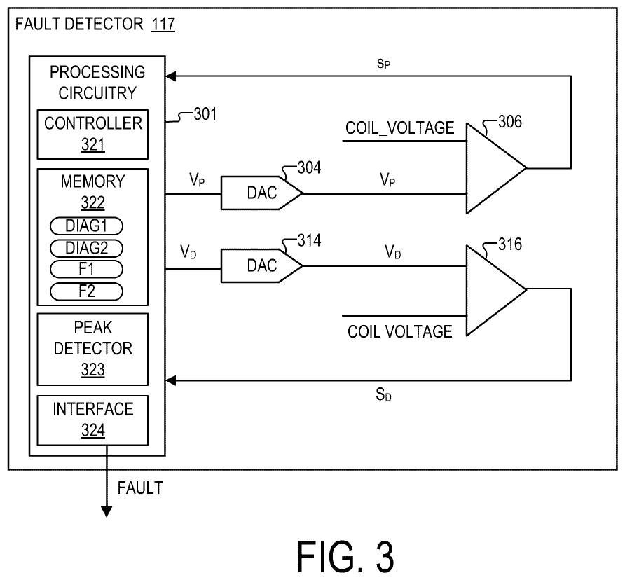

FIG. 3 is a diagram of fault detector 117, according to aspects of the disclosure. In the example of FIG. 3, fault detector 117 includes a processing circuitry 301, a digital-to-analog converter (DAC) 304, a comparator 306, a DAC 314, and a comparator 316. Processing circuitry 301 may include any suitable type of digital or analog circuitry. By way of example, processing circuitry 301 may include a general-purpose processor, an application-specific processor, a signal processor, a peak detector, a memory, one or more amplifiers, one or more analog-to-digital converters, and/or any other suitable type of processing circuitry. In operation, processing circuitry 301 may provide DAC 304 with a signal that is indicative of the value of a threshold V_{P}. DAC 304 may convert the value of threshold V_{P} to analog format and provide the converted threshold V_{P} to comparator 306. Comparator 306 may compare the value of threshold V_{P} to the value of the coil voltage of relay 100 and output a signal S_{P} based on the outcome of the comparison. Processing circuitry 301 may provide DAC 314 with a signal that is indicative of the value of a threshold V_{D}. DAC 314 may convert the threshold V_{D} to analog format and provide the converted threshold to comparator 306. Comparator 316 may compare the value of threshold V_{D} to the value of the coil current of relay 100 and output a signal S_{D} based on the outcome of the comparison. Under the nomenclature of the present disclosure, signals S_{D} and S_{P} are also referred to as “comparison signals”.

A definition is now provided for the term “coil voltage”. According to the present example, the coil voltage of relay 100 is the voltage (relative to ground) that is being applied at the end 241 of coil 113. According to the present example, the coil voltage is the voltage at the drain of transistor T1 (shown in FIG. 2). However, the present disclosure is not limited thereto. The coil voltage of relay 100 may be the voltage at any node in the circuitry that is used to drive relay 100 (e.g., circuitry 202 and 204) that is related to the voltage at the end 241 (or the end 251) of the coil 113. According to the present example, a voltage at a node in the driving circuitry is related to the voltage at end 241 (or end 251) if that voltage can be used, by one of ordinary skill in the art without undue experimentation, to calculate the voltage at end 241 or 251 provided that knowledge is available of the specification parameters of various components that constitute the driving circuitry of the coil 113. The term “positive peak” as used herein refers to a global and/or local maximum in the waveform of the coil voltage of relay 100. The term “negative peak” as used herein refers to a global and/or local minimum in the waveform of the coil voltage of relay 100.

A definition is now provided for the term “coil current”. According to the present example, the coil current of relay 100 is the electrical current that flows through coil 113.

The processing circuitry 301, in one example, may include a controller 321, a memory 322, a peak detector 323, and an interface 324. The controller 321 may include a general-purpose processor, an application-specific processor, a signal processor, and/or any other suitable type of processor. The memory 322 may include any suitable type of volatile and/or non-volatile memory, such as a flash memory or a random access memory. The memory 322 may be configured to store constants DIAG1, DIAG2. Additionally or alternatively, the memory 322 may be configured to store constants F1 and F2. Constants DIAG1, DIAG2, F1, and F2 may be configuration settings that are stored in the memory 322 at the factory, as part of the production process of fault detector 117 or they may be stored in the memory 322 at runtime, by a service technician. Peak detector 323 may include any suitable type of electronic circuitry that is configured to detect positive and/or negative peaks in the waveform of the coil voltage of relay 100. The interface 324 may be a line driver, a serial peripheral interface (SPI), an inter-integrated circuit (I2C) interface, and/or any other suitable type of interface. The interface 324 may be configured to output the signal FAULT. In some implementations, the signal FAULT may be a single-bit signal. Additionally or alternatively, in some implementations, signal FAULT may be a multi-bit signal. Additionally or alternatively, in some implementations, the signal FAULT may be an error code.

The value of the threshold V_{P} may be calculated dynamically by the processing circuitry 301 based on the value of the most recent positive peak in the coil voltage of relay 100. As used herein, the term “most recent positive peak” may refer to the positive peak that was detected last by peak detector 323. In some implementations, the value of the threshold V_{P} may be calculated in accordance with Equation 1 below. Alternatively, in some implementations, the value of the threshold V_{P} may be calculated in accordance with Equation 2 below.

$${V}_{P} = {V}_{pp} + DIAG 1 \qquad ( 1 )$$

$${V}_{P} = {V}_{pp} * F 1 \qquad ( 2 )$$

where V_{P} is the value of threshold V_{P}, V_{PP} is the value of the most recent positive peak in the coil voltage of relay 100, DIAG1 is the value of constant DIAG1 that is stored in memory 322, and F1 is the value of constant F1 that is stored in memory 322.

The value of the threshold V_{D} may be calculated dynamically by the processing circuitry 301 based on the value of the most recent negative peak in the coil voltage of relay 100. As used herein, the term “most recent negative peak” may refer to the negative peak that was detected last by peak detector 323. In some implementations, the value of the threshold V_{D} may be calculated in accordance with Equation 3 below. Alternatively, in some implementations, the value of the threshold V_{D} may be calculated in accordance with Equation 4 below.

$${V}_{D} = {V}_{nn} + DIAG 2 \qquad ( 3 )$$

$${V}_{D} = {V}_{nn} * F 2 \qquad ( 4 )$$

where V_{D} is the value of threshold V_{D}, Vₙₙ is the value of the most recent negative peak in the coil voltage of relay 100, DIAG2 is the value of constant DIAG2 that is stored in memory 322, and F2 is the value of constant F2 that is stored in memory 322.

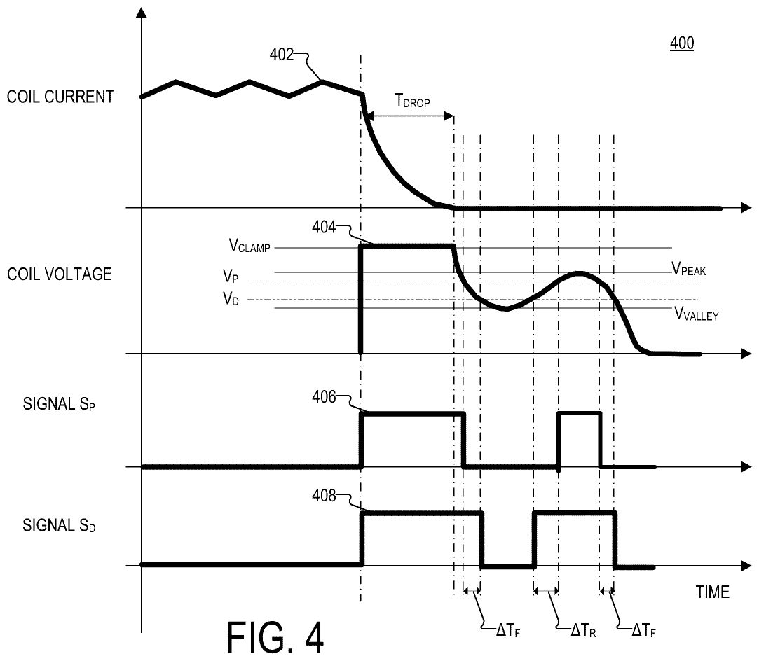

FIG. 4 is a graph 400, which illustrates aspects of the operation of the fault detector 117. Shown in graph 400 are curves 402, 404, 406, and 408. Curve 402 is a plot of the coil current of relay 100. Curve 404 is a plot of the coil voltage of relay 100. Curve 406 is a plot of the signal S_{P} that is calculated by comparator 306. Curve 408 is a plot of signal S_{D} that is calculated by comparator 316. A metric ΔT_{F} is defined as the temporal delay between a given falling edge in the signal S_{P} and a respective falling edge in the signal S_{D}. The respective falling edge in signal S_{D} may be the first falling edge that occurs in signal S_{D} following the occurrence of the given falling edge in signal S_{P}. A metric ΔT_{R} is defined as the temporal delay between a given rising edge in the signal S_{D} and a respective rising edge in the signal S_{P}. The respective rising edge in signal S_{P} may be the first rising edge that occurs in signal S_{P} following the occurrence of the given rising edge in signal S_{D}.

In some respects, FIG. 4 illustrates that contactor 108 (shown in FIG. 1) may be in the hold phase before being disconnected. When transistor T2 and transistor T1 (which are shown in FIG. 2) are both commanded to turn off; the coil current of relay 100 (represented by curve 402) is quenched by allowing the output voltage at node 240, to be pushed high and this permits the application of a negative voltage across the coil 113. The voltage at node 240 is clamped by the Zener diode Z1 to protect transistor T1 and to quickly decay the coil current.

The operation of the Zener diode Z1 can be described as follows. The voltage at node 240 is pushed high by the inductive current during de-energization. Once the clamp voltage, V_{CLAMP} (shown in FIG. 4) is reached, the voltage at node 240 is held at this clamping voltage, V_{CLAMP} until the coil current decays to zero within time T_{DROP}, as shown in FIG. 4. Once the coil current has reached zero, a back electromotive force (EMF) is generated due to the opening movement of contactor 108 until the contactor is fully opened. The generated back EMF behavior can be observed in the voltage at node 240, which varies between positive and negative peak values. The actual voltage at node 240, as noted above, is one example of “the coil voltage” of relay 100.

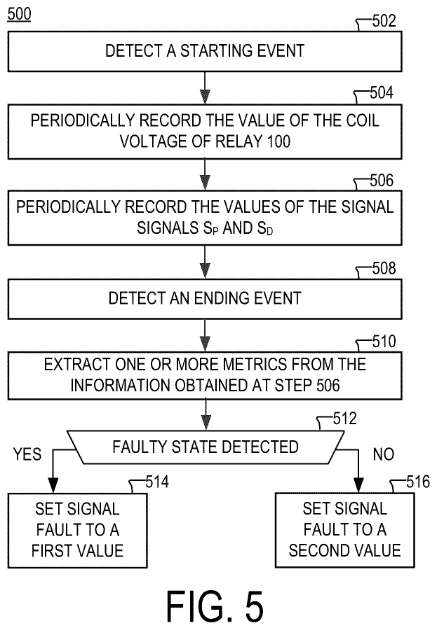

FIG. 5 is a flowchart of an example of a process 500 for detecting faults, according to aspects of the disclosure.

At step 502, processing circuitry 301 detects a starting event. The starting event may be any event that signals that relay 100 is beginning to transition from the active state to the inactive state—i.e., any event that signals that relay 100 is starting to transition from the closed position to the open position. In one example, detecting the starting event may include detecting that the coil current of relay 100 has decreased below a first threshold. In another example, detecting the starting event may include detecting that signal CTRL is set to a value that instructs coil economizer 119 (shown in FIG. 1) to open the relay.

At step 504, processing circuitry 301 periodically records (and/or samples) the value of the coil voltage of relay 100. As noted above, the coil voltage of relay 100 is the voltage at node 240. However, in alternative implementations, the coil voltage of relay 100 may be the voltage at any other node in the coil driver 200, for as long as that voltage is related to the voltage at node 240 and usable to calculate (or otherwise estimate) the voltage at node 240.

At step 506, processing circuitry 301 periodically records (and/or samples) the value of signals S_{P} and S_{D}.

At step 508, processing circuitry 301 detects an ending event. The ending event may be any event that signals that relay 100 has transitioned into the inactive state—i.e., any event that signals that relay 100 has become open. In one example, detecting the ending event may include detecting that the coil current of relay 100 has fallen below a second threshold, wherein the second threshold is lower than the first threshold (considered at step 502).

At step 510, processing circuitry 301 extracts one or more metrics based on the information collected at step 506. According to the present example, the obtained metrics include the values ΔT_{F and} ΔT_{R}, which are discussed above with respect to FIG. 4.

At step 512, processing circuitry 301 processes information obtained at step 510 to determine whether relay 100 is in a faulty state. If relay 100 is found to be in a faulty state, process 500 proceeds to step 514. Otherwise, if relay 100 is found to be operating normally (i.e., not in a faulty state), process 500 proceeds to step 516.

At step 514, processing circuitry 301 sets signal FAULT to a first value (e.g., ‘1’).

At step 516, processing circuitry 301 sets signal FAULT to a second value (e.g., ‘0’).

Although in the present example, the signal FAULT is a 1-bit signal, in alternative implementations the signal FAULT may be a multi-bit signal. In such implementations, when the relay 100 is found to be in a faulty state, the value of the signal FAULT may be set to an error code that identifies the metric whose being out of bounds led processing circuitry 301 to conclude that relay 100 was in a faulty state.

In some implementations, processing circuitry 301 may determine that relay 100 is in a faulty state when any of the metrics obtained at step 510 is out of bounds. According to the present example, any of the metrics obtained at step 510 are out of bounds when the metric fails to meet a lower bound threshold or an upper bound threshold. A metric may fail to meet a lower bound threshold, when the metric is less than the lower bound threshold. The metric may meet the lower bound threshold when the metric is greater than the lower bound threshold. On the other hand, the metric may fail to meet the upper bound threshold when the metric is greater than the upper bound threshold. The metric may meet the upper bound threshold when the metric is less than the upper bound threshold. Although, in the present example, each (or at least one) of the metrics obtained at step 510 is compared against both an upper bound and a lower bound threshold for that metric, alternative implementations are possible in which the metric is compared against only one of the upper bound threshold or the lower bound threshold.

Additionally or alternatively, processing circuitry 301 may determine that relay 100 is in a faulty state when the signals S_{D} and S_{P} indicate that the coil current of relay 100 has failed to cross at least one of the thresholds V_{P} and V_{D} during the period of interest. In some implementations, if the thresholds V_{P} and V_{D} are crossed by the coil current of relay 100 and/or if all of the metrics obtained at step 510 are within predetermined bounds, processing circuitry 301 may determine that relay 100 is operating normally.

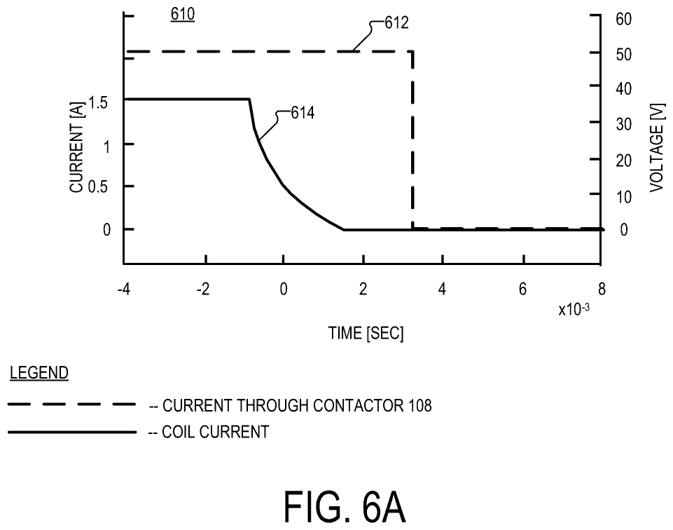

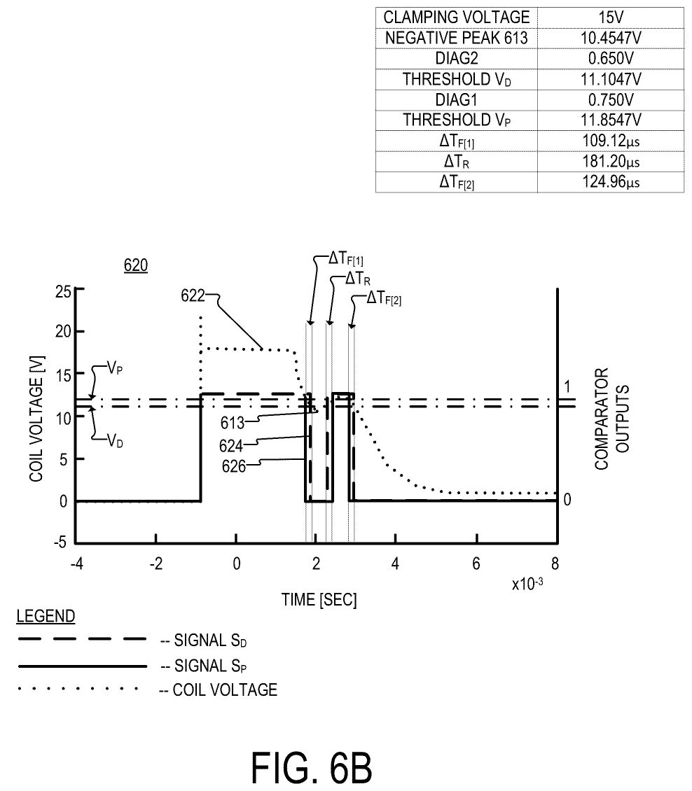

FIGS. 6A-B are graphs illustrating the operation of one possible implementation of relay 100, according to aspects of disclosure. In the example of FIGS. 6A-B, the clamping voltage that is enforced by the Zener diode Z1 is set to 15V. FIG. 6A shows a graph 610, which includes curves 612 and 614. Curve 612 represents the waveform of the electrical current that is flowing through contactor 108 and curve 614 represents the waveform of the coil current of relay 100. FIG. 6B shows a graph 620, which includes curves 622, 624, and 626. Curve 626 represents the waveform of the coil voltage of relay 100, curve 624 represents the waveform of signal S_{P} and curve 626 represents the waveform of signal S_{P}. In the example, of FIGS. 6A-B, the coil voltage of relay 100 has a negative peak 613, which has a value of 10.4547V. Two measurements of the metric ΔT_{F} are taken, which are herein enumerated as ΔT_{F[1]} and ΔT_{F[2]}. In addition, in the example of FIGS. 6A-B one measurement of the metric ΔT_{R} is taken as well. As illustrated, in the example of FIGS. 6A-B, the value of constant DIAG2 is 0.650V, the value of constant DIAG1 is 0.750V, the value of threshold V_{D} is 11.1047V, the value of threshold V_{P} is 11.8547V, the value of ΔT_{F[1]} is 109.12 μs, the value of ΔT_{F[2]} is 124.96, and the value of metric ΔT_{R} is 181.20 μs.

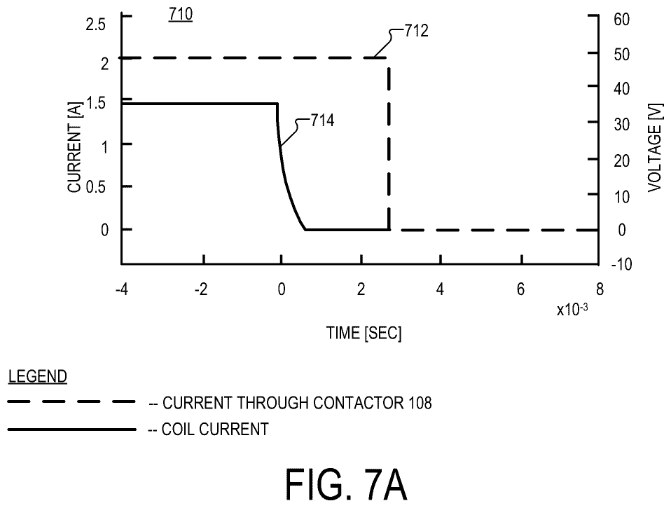

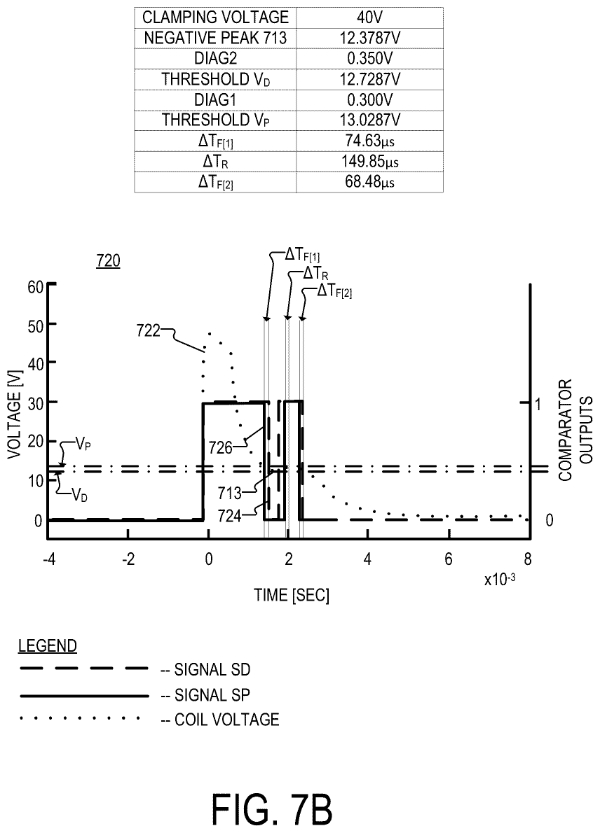

FIGS. 7A-B are graphs illustrating the operation of one possible implementation of relay 100, according to aspects of disclosure. In the example of FIGS. 7A-B, the clamping voltage that is enforced by the Zener diode Z1 is set to 40V. FIG. 7A shows a graph 710, which includes curves 712 and 714. Curve 712 represents the waveform of the electrical current that is flowing through contactor 108 and curve 714 represents the waveform of the coil current of relay 100. FIG. 7B shows a graph 720, which includes curves 722, 724, and 726. Curve 726 represents the waveform of the coil voltage of relay 100, curve 724 represents the waveform of signal S_{P} and curve 726 represents the waveform of signal S_{P}. In the example, of FIGS. 7A-B, the coil voltage of relay 100 has a negative peak 713, which has a value of 12.3787V. Two measurements of the metric ΔT_{F} are taken, which are herein enumerated as ΔT_{F[1]} and ΔT_{F[2]}. In addition, in the example of FIGS. 7A-B one measurement of the metric ΔT_{R} is taken as well. As illustrated, in the example of FIGS. 7A-B, the value of constant DIAG2 is 0.350V, the value of constant DIAG1 is 0.300V, the value of threshold V_{P} is 12.728V, the value of threshold V_{P} is 13.028V, the value of ΔT_{F[1]} is 74.63 μs, the value of ΔT_{R} is 149.85, and the value of metric ΔT_{F[2]} is 68.48 μs.

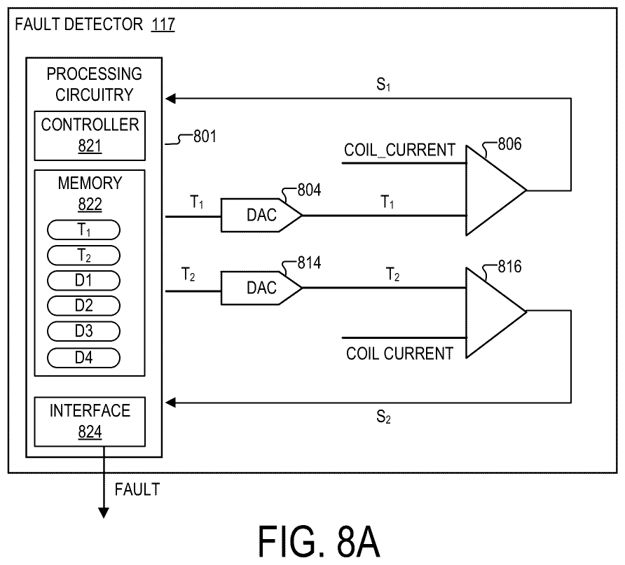

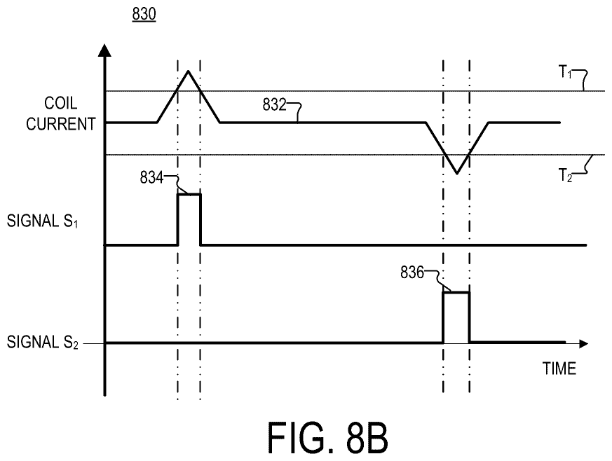

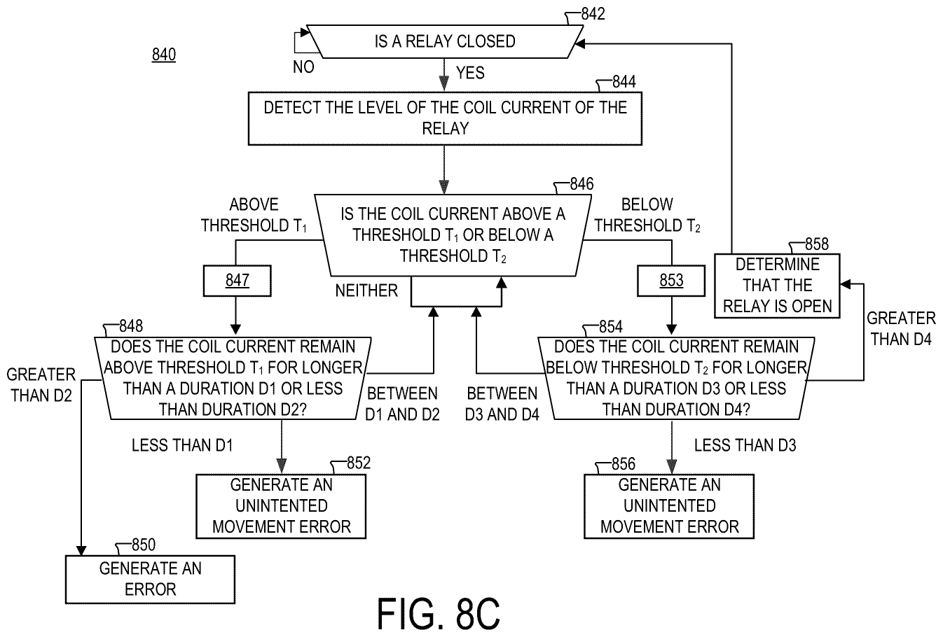

FIG. 8A is a diagram of fault detector 117, according to aspects of the disclosure. In the example of FIG. 8A, fault detector 117 includes a processing circuitry 801, a digital-to-analog converter (DAC) 804, a comparator 806, a DAC 814, and a comparator 816. Processing circuitry 801 may include any suitable type of digital or analog circuitry. By way of example, processing circuitry 801 may include a general-purpose processor, an application-specific processor, a signal processor, a peak detector, a memory, one or more amplifiers, one or more analog-to-digital converters, and/or any other suitable type of processing circuitry. In operation, processing circuitry 801 may provide DAC 804 with a signal that is indicative of the value of a threshold T₁. DAC 804 may convert the value of threshold T₁ to analog format and provide the converted threshold T₁ to comparator 806. Comparator 806 may compare the value of threshold T₁ to the value of the coil current of relay 100 and output a signal S₁ based on the outcome of the comparison. Processing circuitry 801 may provide DAC 814 with a signal that is indicative of the value of a threshold T₂. DAC 814 may convert the threshold T₂ to analog format and provide the converted threshold to comparator 816. Comparator 816 may compare the value of threshold T₂ to the value of the coil current of relay 100 and output a signal T₂ based on the outcome of the comparison. Under the nomenclature of the present disclosure, signals S₁ and S₂ are also referred to as “comparison signals”.

The processing circuitry 801, in one example, may include a controller 821, a memory 822, and an interface 824. The controller 821 may include a general-purpose processor, an application-specific processor, a signal processor, and/or any other suitable type of processor. The memory 822 may include any suitable type of volatile and/or non-volatile memory, such as a flash memory or a random access memory. The memory 822 may be configured to store the values of the thresholds T₁ and T₂. Additionally or alternatively, the memory 822 may be configured to store constants D1 and D2. Constant D1 is the lower boundary and the constant D2 is the upper boundary for a first duration range. Additionally or alternatively, the memory 822 may be configured to store constants D3 and D4. Constant D3 is the lower boundary and the constant D4 is the upper boundary for a second duration range. The interface 824 may be a line driver, a serial peripheral interface (SPI), an inter-integrated circuit (I2C) interface, and/or any other suitable type of interface. The interface 824 may be configured to output a signal FAULT. In some implementations, the signal FAULT may be a single-bit signal. Additionally or alternatively, in some implementations, signal FAULT may be a multi-bit signal. Additionally or alternatively, in some implementations, the signal FAULT may be an error code.

A definition is now provided for the term “unintended movement of contactor 108”. The term “unintended movement” refers to contactor 108 becoming disengaged from fixed contacts 110 for a very short period of time, after which contactor 108 becomes engaged again. During the period in which contactor 108 is disengaged, no current flows between fixed contacts 110 (and/or across relay 100). When contactor 108 becomes re-engaged, electrical current resumes flowing between fixed contacts 110 (and/or across relay 100). Any unintended movement of contactor 108 can bring increased wear on the relay 100 and/or it may be an indication that relay 100 is beginning to fail. For this reason, it is desirable to detect when contactor 108 experiences unintended movement. In this regard, FIGS. 8A-C provide an example of one possible method for detecting unintended movement.

In one example, the contactor 108 is considered to have experienced unintended movement, if the contactor 108 is disengaged for less than 3 ms. In this regard, the value D2 may be set to 3 ms. In the present example, the value D4 is the same as the value D2, however alternative implementations are possible in which the value D4 is different from the value D2.

The method for detecting unintended movement, which discussed with respect to FIGS. 8A-C may work as follows. In some implementations, threshold T₁ may be set to +20% of the expected coil current of relay 100 (and/or +20% of the average coil current), and threshold T₂ may be set to −20% of the expected coil current (and/or −20% of the average coil current) of relay 100. Processing circuitry 801 monitors the value of the coil current of relay 100, after relay 100 is closed. When the coil current of relay 100 crosses one of thresholds T₁ and T₂, processing circuitry 801 detects that contactor 108 has experienced a movement. Next, processing circuitry 801 has to determine next whether the movement was unintended. To make this determination, processing circuitry 801 determines for how long the contactor 108 is disengaged by determining the duration for which the coil current remains above threshold T₁ or below threshold T₂. If the duration is less than 3 ms (or another threshold value), processing circuitry 801 determines that the movement is unintended, and signal FAULT is set to a value that signals an unintended movement error.

FIG. 8B shows a graph 830 illustrating aspects of the operation of fault detector 117, according to aspects of the operation. Graph 830 includes curves 832, 834, and 836. Curve 832 represents the waveform of the coil current of relay 100. Curve 834 represents the waveform of signal S₁. And curve 836 represents the waveform of signal S₂. As illustrated, the signal S₁ may be set to a first value (e.g., logic-high) when the coil current of relay 100 is above the threshold T₁ and at all other times signal S₁ may be set to a second value (e.g., logic-low). Similarly, the signal S₂ may be set to a third value (e.g., logic-high) when the coil current of relay 100 is below the threshold T₂ and at all other times signal S₂ may be set to a fourth value (e.g., logic-low).

FIG. 8C is a flowchart of an example of a process 840, according to aspects of the disclosure.

At step 842, processing circuitry 801 determines if relay 100 is closed. If relay 100 is closed, process 840 proceeds to step 844. Otherwise, if relay 100 is open, step 842 is repeated.

At step 844, processing circuitry 801 detects the level of the coil current of relay 100.

At step 846, processing circuitry 801 determines whether the coil current is above the threshold T₁ or below the threshold T₂. In some implementations, the determination may be based on the values of signals S₁ and S₂, which are discussed above with respect to FIGS. 8A-B. If the coil current of relay 100 is above threshold T₁, process 840 proceeds to step 847. If the coil current of relay 100 is below threshold T₂, process 840 proceeds to step 853. If the coil current is neither above threshold T₁ or below threshold T₂, step 846 is repeated.

At step 847, processing circuitry 801 determines a first duration for which the coil current remains above the threshold T₁. Determining the first duration may include detecting whether the coil current remains above the threshold T₁ for less than the duration D1, for longer than the duration D1 and less than the duration D2, or for longer than the duration D2. In some implementations, step 847 may be performed by periodically sampling the level of the coil current of relay 100 until the coil current falls below threshold T₁ or until the duration D2 passes. According to the present example, D1 is smaller than D2, D1 is the lower bound of a predetermined duration range, and D2 is the upper bound of the predetermined duration range.

At step 848, processing circuitry 801 determines whether the first duration for which the coil current remains above the threshold T₁ is greater than the value D1 and less than the value D2. If the first duration for which the coil current remains above threshold T₁ is greater than the value D2, process 840 proceeds to step 850. If the first duration for which the coil current remains above threshold T₁ is greater than the value D1 and less than the value D2, process 840 returns to step 846. If the first duration for which the coil current remains above the threshold T₁ is less than the value D1, process 840 proceeds to step 852.

At step 850, processing circuitry 801 may generate an error. According to the present example, generating the error may include setting signal FAULT to a first value which indicates the presence of an overcurrent error.

At step 852, processing circuitry 801 generates an indication of an unintended movement error. According to the present example, generating the unintended movement error includes setting the signal FAULT to a second value that is different from the first value. In some implementations, the second value may be an error code specifically indicating that contactor 108 has experienced an unexpected movement.

At step 853, processing circuitry 801 determines a second duration for which the coil current remains below the threshold T₂. Determining the first duration may include detecting whether the coil current remains below the threshold T₂ for less than the duration D3, for longer than the duration D3 and less than the duration D4, or for longer than the duration D4. In some implementations, step 853 may be performed by periodically sampling the level of the coil current of relay 100 until the coil current rises above threshold T₂ or until the duration D4 passes. According to the present example, D3 is smaller than D4, D3 is the lower bound of a predetermined duration range, and D4 is the upper bound of the predetermined duration range.

At step 854, processing circuitry 801 determines whether the second duration for which the coil current remains below the threshold T₂ is greater than the value D3 and less than the value D4. If the duration for which the coil current remains below threshold T₂ is greater than the value D4, process 840 proceeds to step 858. If the duration for which the coil current remains below threshold T₂ is greater than the value D3 and less than the value D4, process 840 returns to step 846. If the duration for which the coil current remains below the threshold T₂ is less than the value D3, process 840 proceeds to step 856.

At step 856, processing circuitry 801 generates an unintended movement error. In one example, generating the unintended movement error may include setting the code to the second value (discussed with respect to step 852). In another example, generating the unintended movement error may include setting the signal FAULT to a third value that is different from the first value and the second value. In this case, the second value and the third value may be both be error codes that correspond to unintended movement, whereby the second value indicates that the unintended movement is manifested in the coil current crossing the threshold T₁ and the third value indicates that the unintended movement is manifested in the coil current crossing the threshold T₂.

At step 858, processing circuitry 801 determines that the movement of contactor 108 was intended and now the relay 100 is open as a result, after which process 840 returns to step 842.

FIG. 8C is provided as an example only. Although, in the example of FIG. 8C, processing circuitry 801 compares the duration for which the coil current of relay 100 remains above threshold T₁ against both of values D1 and D2, in some implementations, processing circuitry 801 may compare the duration against value D1 only. In the example of FIG. 8C, processing circuitry 801 compares the duration for which the coil current of relay 100 remains below threshold T₂ against both of values D3 and D4, in some implementations, processing circuitry 801 may compare the duration against value D3 only. As noted above, in a preferred implementation, values D1 and D3 may be set to “3 milliseconds’, although the exact duration would vary depending on the precise mechanical characteristics of relay 100. In the present example, value D1 is equal to value D3, however in some implementations they can be different.

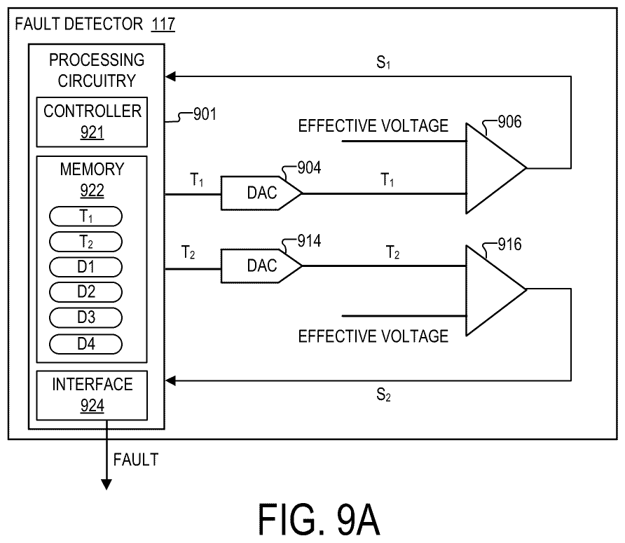

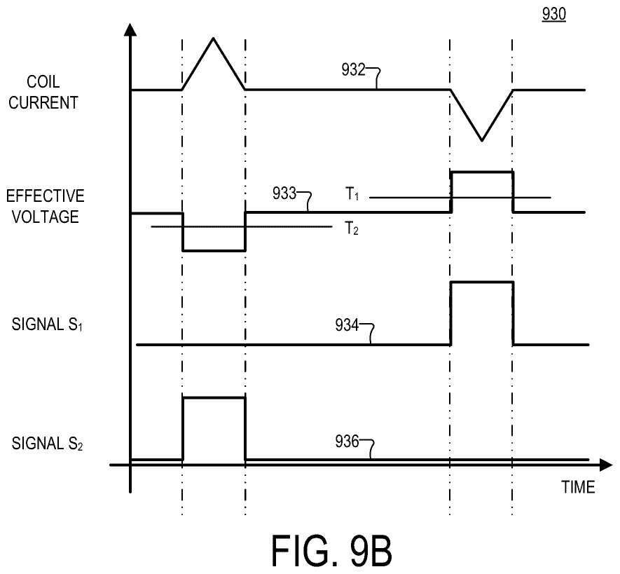

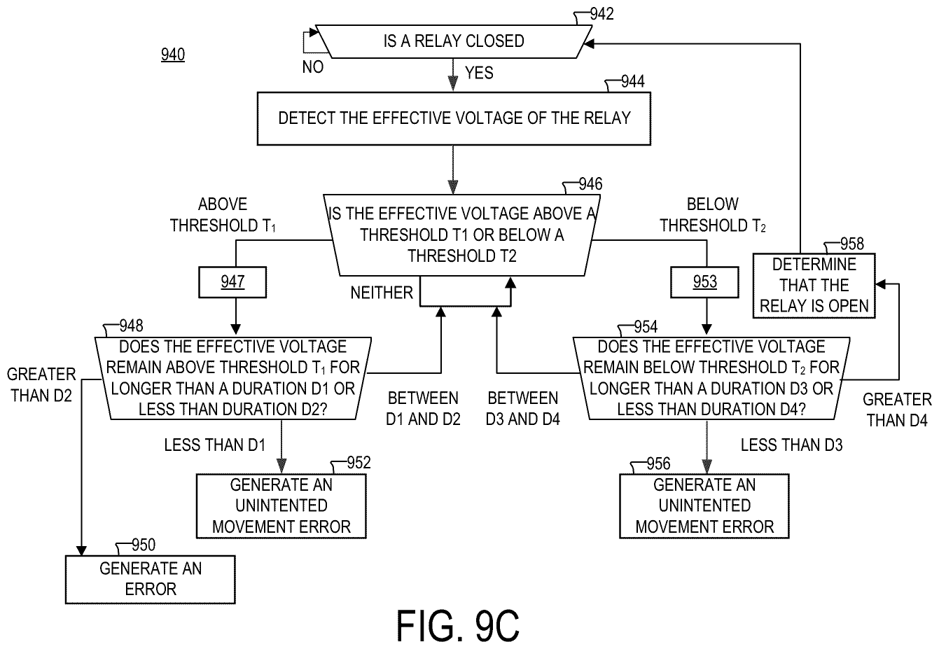

FIG. 9A is a diagram of fault detector 117, according to aspects of the disclosure. In the example of FIG. 9A, fault detector 117 includes a processing circuitry 901, a digital-to-analog converter (DAC) 904, a comparator 906, a DAC 914, and a comparator 916. Processing circuitry 901 may include any suitable type of digital or analog circuitry. By way of example, processing circuitry 901 may include a general-purpose processor, an application-specific processor, a signal processor, a peak detector, a memory, one or more amplifiers, one or more analog-to-digital converters, and/or any other suitable type of processing circuitry. In operation, processing circuitry 901 may provide DAC 904 with a signal that is indicative of the value of a threshold T₁. DAC 904 may convert the value of threshold T₁ to analog format and provide the converted threshold T₁ to comparator 906. Comparator 906 may compare the value of threshold T₁ to the value of the effective voltage of relay 100 and output a signal S₁ based on the outcome of the comparison. Processing circuitry 901 may provide DAC 914 with a signal that is indicative of the value of a threshold T₂. DAC 914 may convert the threshold T₂ to analog format and provide the converted threshold to comparator 906. Comparator 916 may compare the value of threshold T₂ to the value of the effective voltage of relay 100 and output a signal T₂ based on the outcome of the comparison. Under the nomenclature of the present disclosure, signals S₁ and S₂ are also referred to as “comparison signals”.

The processing circuitry 901, in one example, may include a controller 921, a memory 922, and an interface 924. The controller 921 may include a general-purpose processor, an application-specific processor, a signal processor, and/or any other suitable type of processor. The memory 922 may include any suitable type of volatile and/or non-volatile memory, such as a flash memory or a random access memory. The memory 922 may be configured to store the values of the thresholds T₁ and T₂. Additionally or alternatively, the memory 922 may be configured to store constants D1 and D2. Constant D1 is the lower boundary and the constant D2 is the upper boundary for a first duration range. Additionally or alternatively, the memory 922 may be configured to store constants D3 and D4. Constant D3 is the lower boundary and the constant D4 is the upper boundary for a second duration range. The interface 924 may be a line driver, a serial peripheral interface (SPI), an inter-integrated circuit (I2C) interface, and/or any other suitable type of interface. The interface 924 may be configured to output a signal FAULT. In some implementations, the signal FAULT may be a single-bit signal. Additionally or alternatively, in some implementations, signal FAULT may be a multi-bit signal. Additionally or alternatively, in some implementations, the signal FAULT may be an error code.

A definition is now provided for the term “effective voltage of relay 100”. According to the present disclosure, the effective voltage of relay 100 is the product of the battery voltage of relay 100 and the duty cycle of relay 100. The battery voltage of relay 100 is the voltage that is used to energize the coil 113 of relay 100. In one example, the battery voltage may be the voltage that the battery used to open and close relay 100 is able to put out. The duty cycle of relay 100 is the turn on time during current regulation used to drive the coil 113 during the hold phase. The hold phase is the time period which begins when the contactor 108 comes in electrical contact with fixed contacts 110 and ends the electrical contact is interrupted. In some implementations, the duty cycle of relay 100 can be calculated by processing circuitry 901 in accordance with equation 5 below, and the effective voltage of relay 100 can be calculated by processing circuitry 901 in accordance with equation 6 below.

$$DC = \frac{CR * HC}{BSV} * DD \qquad ( 5 )$$

$${V}_{E} = BSV * DC \qquad ( 6 )$$

Where DC is the duty cycle of relay 100, BSV is the battery supply voltage of relay 100, the CR is the coil resistance of relay 100 (i.e., the resistance of coil 113), and HC is the hold current of relay 100 (i.e., the electrical current that flows through coil 113 when relay 100 is in the hold phase).

FIGS. 9A-C are provided to illustrate an example of another method for detecting unintended movement of contactor 108. In some implementations, the method may work as follows. Threshold T₁ may be set to +20% of the expected effective voltage of relay 100 (and/or +20% of the average effective voltage), and threshold T₂ may be set to −20% of the expected effective voltage of relay 100 (and/or −20% of the average effective voltage) of relay 100. Processing circuitry 901 monitors the value of the effective voltage of relay 100 after relay 100 is closed. When the effective voltage of relay 100 crosses one of thresholds T₁ and T₂, processing circuitry 901 detects that contactor 108 has experienced a movement. Next, after relay 100 is closed processing circuitry 901 has to determine next whether the movement was unintended. To make this determination, processing circuitry 901 determines for how long the contactor 108 is disengaged by determining the duration for which the effective voltage remains above threshold T₁ or below threshold T₂. If the duration is less than 3 ms (or another threshold value), processing circuitry 901 determines that the movement is unintended, and signal FAULT is set to a value that signals an unintended movement error.

For ease of description, the example of FIGS. 9A-C uses the same notation to designate the thresholds that are used by comparators 906 and 916 (i.e., thresholds T₁ and T₂), the outputs of comparators 906 and 916 (i.e., signals S₁ and S₂), and the parameters D1-D4, which define the acceptable ranges for diagnosing an unintended movement of contactor 108. However, it will be understood that the thresholds T₁ and T₂, which are discussed with respect to FIGS. 9A-C, may have different values than the thresholds T₁ and T₂, which are discussed with respect to FIGS. 8A-C. Similarly, it will be understood that signals S₁ and S₂ which are discussed with respect to FIGS. 9A-C are generated as a result of comparing the effective voltage of relay 100 to voltage thresholds T₁ and T₂, whereas signals S₁ and S₂ which are discussed with respect to FIGS. 8A-C are generated as a result of comparing the effective voltage of relay 100 against effective voltage thresholds T₁ and T₂. Similarly, the parameters D1-D4, which are discussed with respect to FIGS. 9A-C, may have different values from the parameters D1-D4, which are discussed with respect to FIGS. 8A-C.

FIG. 9B shows a graph 930 illustrating aspects of the operation of fault detector 117, according to aspects of the operation. Graph 930 includes curves 932, 933, 934, and 936. Curve 932 represents the waveform of the coil current of relay 100. Curve 933 represents the waveform of the effective voltage of relay 100. Curve 934 represents the waveform of signal S₁. And curve 936 represents the waveform of signal S₂. As illustrated, the signal S₁ may be set to a first value (e.g., logic-high) when the effective voltage of relay 100 is above the threshold T₁ and at all other times signal S₁ may be set to a second value (e.g., logic-low). Similarly, the signal S₂ may be set to a third value (e.g., logic-high) when the effective voltage of relay 100 is below the threshold T₂ and at all other times signal S₂ may be set to a fourth value (e.g., logic-low).

FIG. 9C is a flowchart of an example of a process 940, according to aspects of the disclosure.

At step 942, processing circuitry 901 determines if relay 100 is closed. If relay 100 is closed, process 940 proceeds to step 944. Otherwise, if relay 100 is open, step 942 is repeated.

At step 944, processing circuitry 901 detects the level of the effective voltage of relay 100.

At step 946, processing circuitry 901 determines whether the effective voltage is above the threshold T₁ or below the threshold T₂. In some implementations, the determination may be based on the values of signals S₁ and S₂, which are discussed above with respect to FIGS. 9A-B. If the effective voltage of relay 100 is above threshold T₁, process 940 proceeds to step 947. If the effective voltage of relay 100 is below threshold T₂, process 940 proceeds to step 953. Otherwise, if the effective voltage of relay 100 is between threshold T₂ and T₁, step 946 is repeated.

At step 947, processing circuitry 801 determines a first duration for which the effective voltage remains above the threshold T₁. Determining the first duration may include detecting whether the effective voltage remains above the threshold T₁ for less than the duration D1, for longer than the duration D1 and less than the duration D2, or for longer than the duration D2. In some implementations, step 847 may be performed by periodically calculating (and/or sampling) the effective voltage of relay 100 until the effective voltage falls below threshold T₁ or until the duration D2 passes. According to the present example, D1 is smaller than D2, D1 is the lower bound of a predetermined duration range, and D2 is the upper bound of the predetermined duration range.

At step 948, processing circuitry 901 determines whether the first duration for which the effective voltage remains above the threshold T₁ is greater than the value D1 and less than the value D2. If the first duration for which the effective voltage remains above threshold T₁ is greater than the value D2, process 940 proceeds to step 950. If the first duration for which the effective voltage remains above threshold T₁ is greater than the value D1 and less than the value D2, process 940 returns to step 946. If the duration for which the effective voltage remains above the threshold T₁ is less than the value D1, process 940 proceeds to step 952.

At step 950, processing circuitry 901 may generate an error. According to the present example, generating the error may include setting signal FAULT to a first value which indicates the presence of excessive effective voltage.

At step 952, processing circuitry 901 generates an unintended movement error. According to the present example, generating the unintended movement error includes setting the signal FAULT to a second value that is different from the first value. In some implementations, the second value may be an error code indicating that contactor 108 has experienced an unexpected movement.

At step 953, processing circuitry 801 determines a second duration for which the effective voltage remains below the threshold T₂. Determining the second duration may include detecting whether the effective voltage remains below the threshold T₂ for less than the duration D3, for longer than the duration D3 and less than the duration D4, or for longer than the duration D4. In some implementations, step 853 may be performed by periodically calculating (and/or sampling) the effective voltage of relay 100 until the effective voltage rises above threshold T₂ or until the duration D4 passes. According to the present example, D3 is smaller than D4, D3 is the lower bound of a predetermined duration range, and D4 is the upper bound of the predetermined duration range.

At step 954, processing circuitry 901 determines whether the duration for which the effective voltage remains below the threshold T₂ is greater than the value D3 and less than the value D4. If the second duration for which the effective voltage remains below threshold T₂ is greater than the value D4, process 940 proceeds to step 958. If the second duration for which the effective voltage remains below threshold T₂ is greater than the value D3 and less than the value D4, process 940 returns to step 946. If the second duration for which the effective voltage remains below the threshold T₂ is less than the value D3, process 940 proceeds to step 956.

At step 956, processing circuitry 901 generates an unintended movement error. In one example, generating the unintended movement error may include setting the code to the second value (discussed with respect to step 952). In another example, generating the unintended movement error may include setting the signal FAULT to a third value that is different from the first value and the second value. In this case, the second value and the third value may both be error codes that correspond to unintended movement, whereby the second value indicates that the unintended movement is manifested in the effective voltage crossing the threshold T₁ and the third value indicates that the unintended movement is manifested in the effective voltage crossing the threshold T₂.

At step 958, processing circuitry 901 determines that the movement of contactor 108 was intended and now the relay 100 is open as a result, after which process 940 returns to step 942.

FIG. 9C is provided as an example only. Although, in the example of FIG. 9C, processing circuitry 901 compares the duration for which the effective voltage of relay 100 remains above threshold T₁ against both of values D1 and D2, in some implementations, processing circuitry 901 may compare the duration against value D1 only. In the example of FIG. 9C, processing circuitry 901 compares the duration for which the effective voltage of relay 100 remains below threshold T₂ against both of values D3 and D4, in some implementations, processing circuitry 901 may compare the duration against value D3 only. As noted above, in a preferred implementation, values D1 and D3 may be set to “3 milliseconds’, although the exact duration would vary depending on the exact mechanical characteristics of relay 100. In the present example, value D1 is equal to value D3, however in some implementations they can be different.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A method, comprising:
generating a comparison signal S_{P} having a first value when a voltage that is applied at one end of a contactor coil of a relay is above a threshold V_{P} and a second value when the voltage is below the threshold V_{P};
generating a comparison signal S_{D} having the first value when the voltage is above a threshold V_{D} and the second value when the voltage is below the threshold V_{D};
detecting whether the relay is in a faulty state based on the comparison signals S_{P} and S_{D}; and
generating an indication of a fault when the relay is detected to be in a faulty state.

2. The method of claim 1, wherein the end of the relay is coupled to a drain of a transistor, the transistor being part of a driving circuitry for the coil, and the voltage being a drain voltage of the transistor.

3. The method of claim 1, wherein:
detecting whether the relay is in a faulty state includes identifying a delay between a first type-1 edge in one of the comparison signals S_{P} and S_{D} and a second type-1 edge in the other one of the comparison signals S_{P} and S_{S}, and determining that relay is in a faulty state when the delay fails to meet a delay threshold, and
the second type-1 edge is generated immediately after the first type-1 edge.

4. The method of claim 3, wherein the first type-1 edge is a rising edge and the second type-1 edge is a rising edge.

5. The method of claim 3, wherein the first type-1 edge is a falling edge and the second type-1 edge is a falling edge.

6. The method of claim 3, wherein the delay threshold is an upper bound threshold, the delay meets the upper bound threshold when the delay is less than the upper bound threshold, and the delay fails to meet the upper bound threshold when the delay is greater than the upper bound threshold.

7. The method of claim 3, wherein the delay threshold is a lower bound threshold, the delay meets the lower bound threshold when the delay is greater than the lower bound threshold, and the delay fails to meet the lower bound threshold when the delay is less than the lower bound threshold.

8. A system, comprising:
a first comparator that is configured to generate a comparison signal S_{P}, the comparison signal S_{P} having a first value when a voltage that is applied at one end of a contact coil of a relay is above a threshold V_{P} and a second value when the voltage is below the threshold V_{P};
a second comparator that is configured to generate a comparison signal S_{D}, the comparison signal S_{D} having the first value when the voltage is above a threshold V_{D} and the second value when the voltage is below the threshold V_{D}; and
a processing circuitry that is configured to detect whether the relay is in a faulty state based on the comparison signals S_{P} and S_{D}, and generate an indication of a fault when the relay is detected to be in a faulty state.

9. The system of claim 8, wherein the end of the relay is coupled to a drain of a transistor, the transistor being part of a driving circuitry for the coil, and the voltage being a drain voltage of the transistor.

10. The system of claim 8, wherein:
detecting whether the relay is in a faulty state includes identifying a delay between a first type-1 edge in one of the comparison signals S_{P} and S_{D} and a second type-1 edge in the other one of the comparison signals S_{P} and S_{D}, and determining that relay is in a faulty state when the delay fails to meet a delay threshold, and
the second type-1 edge is generated immediately after the first type-1 edge.

11. The system of claim 10, wherein the first type-1 edge is a rising edge and the second type-1 edge is a rising edge.

12. The system of claim 10, wherein the first type-1 edge is a falling edge and the second type-1 edge is a falling edge.

13. The system of claim 10, wherein the delay threshold is an upper bound threshold, the delay meets the upper bound threshold when the delay is less than the upper bound threshold, and the delay fails to meet the upper bound threshold when the delay is greater than the upper bound threshold.

14. The system of claim 10, wherein the delay threshold is a lower bound threshold, the delay meets the lower bound threshold when the delay is greater than the lower bound threshold, and the delay fails to meet the lower bound threshold when the delay is less than the lower bound threshold.

15. A method, comprising:
detecting a metric of a relay;
detecting whether the metric has crossed a threshold;
when the metric has crossed the threshold, detecting a duration for which the metric remains past the threshold; and
generating an unintended movement error when the metric remains past the threshold for less than a lower bound duration.

16. The method of claim 15, wherein the metric includes a coil current of the relay.

17. The method of claim 15, wherein the metric includes an effective voltage of the relay, the coil voltage being based on a product of a voltage used to energize a coil of the relay and a duty cycle that is used to maintain the relay in a hold state.

18. The method of claim 15, wherein the threshold includes a high threshold, and detecting a duration for which the metric remains past the threshold includes detecting a duration for which the metric remains above the high threshold.

19. The method of claim 15, wherein the threshold includes a low threshold, and detecting a duration for which the metric remains past the threshold includes detecting a duration for which the metric remains below the low threshold.

20. The method of claim 15, wherein the threshold includes a high threshold, and detecting a duration for which the metric remains past the threshold includes detecting a duration for which the metric remains above the threshold, the method further comprising generating an overcurrent error when the metric remains above the high threshold for longer than an upper bound duration.

21. The method of claim 20, further comprising generating the unintended movement error includes outputting a first error code and generating the overcurrent error includes outputting a second error code that is different from the first error code.

22. A system, comprising:
a processing circuitry configured to:
detect a metric of a relay;
detect whether the metric has crossed a threshold;
when the metric has crossed the threshold, detect a duration for which the metric remains past the threshold; and
generate an unintended movement error when the metric remains past the threshold for less than a lower bound duration.

23. The system of claim 22, wherein the metric includes a coil current of the relay.

24. The system of claim 22, wherein the metric includes an effective voltage of the relay, the effective voltage being based on a product of a voltage used to energize a coil of the relay and a duty cycle that is used to maintain the relay in a hold state.

25. The system of claim 22, wherein the threshold includes a high threshold, and detecting a duration for which the metric remains past the threshold includes detecting a duration for which the metric remains above the high threshold.

26. The system of claim 22, wherein the threshold includes a low threshold, and detecting a duration for which the metric remains past the threshold includes detecting a duration for which the metric remains below the low threshold.

27. The system of claim 22, wherein the threshold includes a high threshold, detecting a duration for which the metric remains past the threshold includes detecting a duration for which the metric remains above the threshold, and the processing circuitry is further configured to generate an overcurrent error, when the metric remains above the high threshold for longer than the upper bound duration.

28. The system of claim 27, wherein comprising generating the unintended movement error includes outputting a first error code and generating the overcurrent error includes outputting a second error code that is different from the first error code.
